(19) United States
(12) Patent Application Publication
(10) Pub. No.: US 2025/0231837 A1
(43) Pub. Date: Jul. 17, 2025

(54) TOLERATING DEFECTIVE MEMORY BANKS IN EMERGING MEMORY COMPONENTS

(71) Applicant: Sandisk Technologies, Inc., Milpitas, CA (US)

(72) Inventors: Lunkai Zhang, Portland, OR (US); Raj Ramanujan, Federal Way, WA (US); Martin Lueker-Boden, Fremont, CA (US)

(21) Appl. No.: 18/413,391

(22) Filed: Jan. 16, 2024

(51) Int. Cl. G06F 11/14

(52) U.S. Cl. CPC G06F 11/142; G06F 2201/86

(57) ABSTRACT

A memory device includes a controller and an addressing system that enables the memory device to support memory components having one or more defective memory banks. During a testing phase of a memory component manufacturing process, memory components with defective memory banks are identified and a memory bank remapping process is initiated. During the remapping process, entries in a bank remapping register array are updated such that available physical memory banks are logically mapped in a consecutive order. Memory components having the same number of available memory banks are grouped and used in a memory device. If the number of available memory banks of each memory component is not a power of two, a mod division circuit is used to generate a memory component address for the memory component. The memory component address includes a bank identifier and an intra-bank address.

### BACKGROUND

State-of-the-art memory devices are being developed in which the memory dies of the memory device include a number of memory banks. A memory bank is the largest physical granularity of the memory die. Each memory bank is typically addressed and accessed with other memory banks. For example, memory banks of a memory die are accessed in parallel.

The number of memory banks on the memory die is typically a power of two. For example, a memory die can have eight memory banks, sixteen memory banks, thirty-two memory banks, sixty-four memory banks, etc. However, if a single memory bank on a memory die is faulty or broken, the entire memory die is unusable.

During early productization stages, the memory bank defect rate of a memory die can be relatively high. This negatively affects the yield of memory dies and/or memory devices. Accordingly, it would be beneficial to increase the yield of memory dies and corresponding memory devices by enabling the memory device to support memory dies having one or more defective memory banks.

### SUMMARY

Examples of the present disclosure describe a memory device that supports memory dies having one or more defective memory banks. In an example, during a testing phase and/or a sorting phase of a memory die manufacturing process, the memory die undergoes a testing process to determine whether one or more memory banks of the memory die are defective. If it is determined the memory die includes at least one defective memory bank, a memory bank remapping process is initiated.

For example, a memory die includes a bank remapping register array. The bank remapping register array indicates a logical to physical mapping between a bank identifier of a memory die address and a physical memory bank of the memory die. For example, the bank remapping register array includes a number of entries, and each entry includes a value that corresponds to a particular physical memory bank of the memory die. Thus, a bank identifier of “31” corresponds to a thirty-first entry of the bank remapping register array. The thirty-first entry of the bank remapping register array includes a value of 31, which indicates the thirty-first memory bank of the memory die is associated with the bank identifier of 31.

However, the mapping between bank identifiers and physical memory banks needs to be updated if the memory die includes one or more defective memory banks. The mapping between the bank identifiers and the physical memory banks is updated as part of the memory bank remapping process. During the memory bank remapping process, the values of entries in the bank remapping register array are changed or updated such that available physical memory banks are logically mapped in a consecutive order.

For example, if the second physical memory bank in the memory die is identified as defective, the value of the second entry in the bank remapping register array is updated to correspond to an available memory bank. Because the value of the entry in the bank remapping register array is updated to correspond to an available memory bank, the bank identifier associated with the entry having the updated value maps to an available physical memory bank of the memory die instead of the defective physical memory bank of the memory die.

For example, the value of the second entry of the bank remapping register array is changed from a “2” to a “31” (which corresponds to the thirty-first memory bank of the memory die). As a result, a bank identifier of “2” is logically mapped, using the bank remapping register array, to the thirty-first physical memory bank instead of the second physical memory bank (which is defective).

During a sorting phase of the memory die manufacturing process, memory dies with the same number of available memory banks are identified and grouped. When constructing a memory device with two or more memory dies, the memory device includes memory dies having the same number of available memory banks. If the memory device includes memory dies having a non-power-of-two number of memory components, a new memory component address is generated using a mod division circuit. In an example, the new memory component address includes a bank identifier and an intra-bank address.

Accordingly, examples of the present disclosure describe a method that includes identifying a defective memory bank of a memory component. In an example, the memory component has a plurality of memory banks and each memory bank of the plurality of memory banks is associated with an entry in a bank remapping register array. In an example, the entry in the bank remapping register array indicates a logical to physical mapping between a bank identifier of a memory component address associated with the memory component and a corresponding memory bank of the plurality of memory banks. The method also includes updating a value of an entry in the bank remapping register array that is associated with the defective memory bank. In an example, updating the value of the entry in the bank remapping register array consolidates entries in the bank remapping register array that are associated with available memory banks of the plurality of memory banks.

Examples also describe a memory device that includes one or more memory components. Each of the one or more memory components includes a plurality of memory banks. The memory device also includes a controller communicatively coupled to the one or more memory components. In an example, the controller is operable to determine whether at least one memory component of the one or more memory components includes a non-power-of-two number of memory banks. If it is determined that the one or more memory components includes the non-power-of-two number of memory components, the controller generates a memory component address for the at least one memory component.

Other examples describe a memory device having means for determining whether a memory component includes a non-power-of-two number of memory means. The memory device also includes means for generating a new memory component address for the memory component having the non-power-of-two number of memory means.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1 is a block diagram of a system that includes a host device and a memory device according to an example.

FIG. 2 illustrates a memory device having a controller and a number of memory components according to an example.

FIG. 3A illustrates a mapping between a bank identifier of a component address associated with a memory component and physical memory banks of the memory component according to an example.

FIG. 3B illustrates how entries in the bank remapping register array of FIG. 3A are consolidated during a memory bank remapping process according to an example.

FIG. 4 illustrates how memory components having the same number of available memory banks are grouped to form ranks according to an example.

FIG. 5 illustrates how a memory component address having a bank identifier and an intra-bank address is generated for a memory component having a non-power-of-two number of memory banks according to an example.

FIG. 6 illustrates a method for remapping memory banks of a memory component according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. The following detailed description is therefore not to be taken in a limiting sense, and the scope of the present disclosure is defined by the appended claims and their equivalents.

Newer, state-of-the-art memory devices include memory dies having an array of memory banks. The number of memory banks of each memory die is typically a power of two. A controller associated with the memory device interacts with each of the memory dies using an operation/address bus and a data bus. The operation/address bus broadcasts one or more operations to each of the memory dies using an in-memory die address. As such, all of the memory dies receive the same operations/addresses at the same time. The in-memory die address also includes a memory bank identifier. For a particular operation, the memory bank identifier is the same across each memory die. The data bus is a segmented bus that transfers read/write data between the controller and each of the memory dies.

During a broadcast operation, the controller requests, via the operation/broadcast bus, data from a particular memory bank (e.g., memory bank fifteen). The request is sent, in parallel, to each memory die. In response, each memory die returns data from the particular memory bank via the data bus. The controller can then combine the received data. However, as previously described, if a single memory bank on a memory die is faulty or broken, the entire memory die is unusable.

To address the above, examples of the present disclosure describe a memory die testing/repairing/sorting mechanism and a memory device that supports memory dies having one or more defective memory banks. In an example, during a testing phase and/or a sorting phase of a memory die manufacturing process, one or more memory dies are tested to determine whether the memory die includes one or more defective memory banks. When it is determined that a particular memory die includes one or more defective memory banks, a memory bank remapping process is initiated to ensure entries in a bank remapping register array that are associated with the available/good memory banks are consecutive from a first entry in the bank remapping register array (e.g., entry 0) to an Nth entry in the bank remapping register array. It will be understood by those of skill in the art that testing a memory device and/or a memory die may include running tests such as iterative programming of addresses of a memory die, burn-in testing of memory dies, or executing self-test circuitry of a memory die.

When the bank remapping register array entries associated with the available/good memory banks are consolidated, a grouping/sorting phase is initiated in which memory dies having the same number of available memory banks are grouped and subsequently added to or are otherwise included with a memory device. For example, a memory device includes memory dies with thirty one available memory banks. In another example, the memory device includes one or more memory dies having thirty available memory banks. Additionally, a mod division circuit is used generate memory die addresses (e.g., an intra-bank address and/or a bank identifier) that is issued to each memory die in the memory device.

In accordance with the above, many technical benefits may be realized including, but not limited to, improving yield of memory devices using emerging memory technology—especially in memory devices that are in early product development stage.

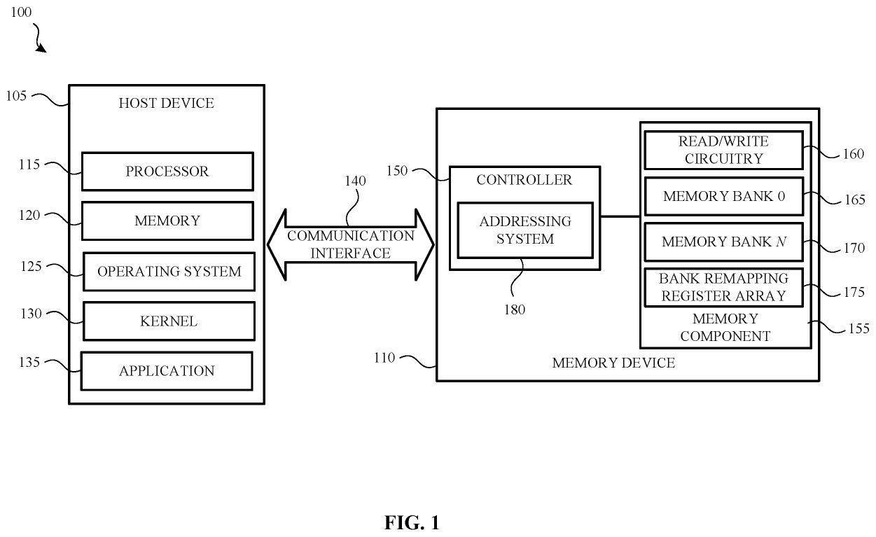

These benefits, along with other examples, will be shown and described in greater detail with respect to FIG. 1-FIG. 6.

FIG. 1 is a block diagram of a system 100 that includes a host device 105 and a memory device 110 according to an example. In an example, the memory device 110 is part of a data storage device. In an example, the host device 105 includes a processor 115 and a memory 120 (e.g., main memory). The memory 120 includes or is otherwise associated with an operating system 125, a kernel 130 and/or an application 135.

The processor 115 can execute various instructions, such as, for example, instructions from the operating system 125 and/or the application 135. The processor 115 includes circuitry such as a microcontroller, a Digital Signal Processor (DSP), an Application-Specific Integrated Circuit (ASIC), a Field Programmable Gate Array (FPGA), hard-wired logic, analog circuitry and/or various combinations thereof. In an example, the processor 115 includes a System on a Chip (SoC).

In an example, the memory 120 is used by the host device 105 to store data that is used, or otherwise executed by, the processor 115. Data stored in the memory 120 includes instructions provided by the memory device 110 via a communication interface 140. The data stored in the memory 120 also includes data used to execute instructions from the operating system 125 and/or one or more applications 135. In an example, the memory 120 is a single memory. In another example, the memory 120 includes multiple memories, such as, for example, one or more non-volatile memories, one or more volatile memories, or a combination thereof.

In an example, the operating system 125 creates a virtual address space for the application 135 and/or other processes executed by the processor 115. The virtual address space maps to locations in the memory 120. The operating system 125 also includes, or is otherwise associated with, a kernel 130. In an example, the kernel 130 includes instructions for managing various resources of the host device 105 (e.g., memory allocation), handling read and write requests and performing other operations.

The communication interface 140 communicatively couples the host device 105 and the memory device 110. The communication interface 140 may be a Serial Advanced Technology Attachment (SATA), a PCI express (PCIe) bus, a Small Computer System Interface (SCSI), a Serial Attached SCSI (SAS), Ethernet, Fibre Channel, or Wi-Fi. As such, the host device 105 and the memory device 110 need not be physically co-located and may communicate over a network such as a Local Area Network (LAN) or a Wide Area Network (WAN), such as the internet. In addition, the host device 105 interfaces with the memory device 110 using a logical interface specification such as Non-Volatile Memory express (NVMe) or Advanced Host Controller Interface (AHCI).

The memory device 110 also includes a controller 150. In an example, the controller 150 receives data and/or instructions from the host device 105. The controller 150 also sends data to the host device 105. For example, the controller 150 can send data to and/or receive data from the host device 105 via the communication interface 140.

The memory device 110 also includes a memory component 155. Although a single memory component 155 is shown, the memory device 110 can include a number of different memory components 155. In an example, the memory component 155 is a memory die (or a semiconductor die) having a number of memory banks. For example, the memory component 155 includes Memory Bank 0 165 and Memory Bank N 170.

In an example, the memory banks are the largest physical granularity of the memory component-similar to the concept of plane in NAND Flash. Each memory bank is addressed and/or accessed together. For example, Memory Bank 0 165 and Memory Bank N 170 include memory cells that can be read from and/or written to simultaneously and/or in parallel. Because the memory banks are accessed in parallel, the data transfer rate of the memory component 155 is enhanced when compared with other memory devices that do not support memory banks that are accessible in parallel.

In an example, the number of memory banks of the memory component 155 is a power of two. For example, the memory component 155 can have eight memory banks, sixteen memory banks, thirty-two memory banks and so on. Although a specific number of memory banks are discussed, the memory component 155 may include any number of memory banks. The memory banks may be one-time programmable, few-time programmable, or many-time programmable and may be arranged in any configuration. Additionally, the memory banks may be volatile memory banks or non-volatile memory banks.

The controller 150 sends data and/or commands to, and/or receives data from, the memory component 155. For example, the controller 150 sends data and a corresponding write command to the memory component 155 which causes the memory component 155 to store data at a specified address associated with one or more of memory banks.

In an example, the controller 150 is communicatively coupled to the memory component 155 using one or more busses. For example, the controller 150 is communicatively coupled to the memory component 155 using an operation/address bus and/or a data bus. In an example, the operation/address bus broadcasts various operations to each memory component 155 of the memory device 110. The data bus is a segmented bus that transfers read/write data between the controller 150 and the memory component 155.

In some examples, the memory device 110 is attached to or embedded within the host device 105. In another example, the memory device 110 is implemented as an external device or a portable device that can be communicatively or selectively coupled to the host device 105. In yet another example, the memory device 110 is a component (e.g., a solid-state drive (SSD)) of a network accessible data storage system, a network-attached storage system, a cloud data storage system, and the like.

The memory component 155 also includes support circuitry. In an example, the support circuitry includes read/write circuitry 160. The read/write circuitry 160 supports the operations on the memory banks of the memory component 155. Although the read/write circuitry 160 is depicted as a single component, in other examples the read/write circuitry 160 is divided into separate components, such as, for example, read circuitry and write circuitry. In an example, the read/write circuitry 160 is external to the memory component 155. In another example, each memory component 155 includes corresponding read/write circuitry 160 that is operable to read data from and/or write data to the memory banks independent of other read and/or write operations on any of the other memory components 155.

The memory component 155 also includes a bank remapping register array 175. The bank remapping register array 175 includes a number of entries and each entry indicates a logical to physical mapping between the bank remapping register array and physical memory banks of the memory component 155. In an example, the bank remapping register array 175 maps a bank identifier of a system address associated with the memory component and/or a memory bank to a physical memory bank. For example, one entry or value in the bank remapping register array 175 corresponds to Memory Bank 0 165 while another entry or value in the bank remapping register array 175 corresponds to Memory Bank N 170.

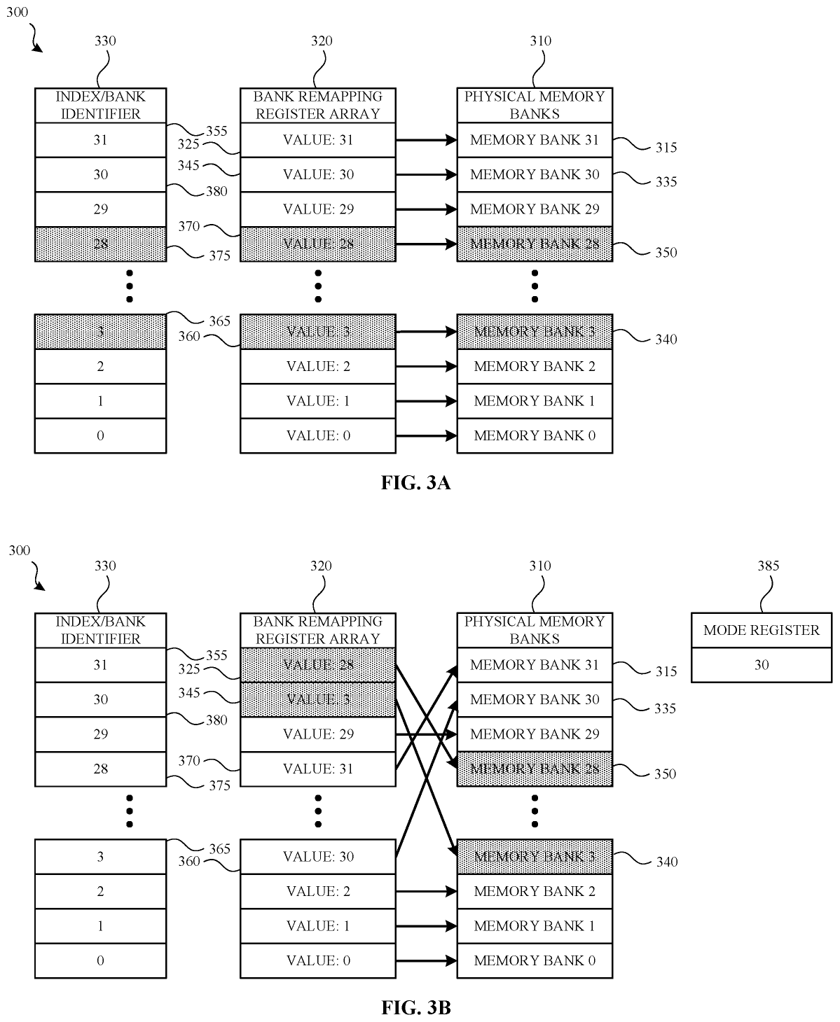

As will be explained in greater detail with respect to FIG. 3A-FIG. 3B, if one or more of Memory Bank 0 165 or Memory Bank N 170 is defective, a memory bank remapping process is initiated. During the memory bank remapping process, entries or values in the bank remapping register array 175 that correspond to physical memory banks are changed such that the available memory banks of the memory component 155 are logically mapped to the physical memory banks in a consecutive order.

The controller 150 also includes or is otherwise associated with an addressing system 180. The addressing system 180 determines or identifies whether the memory component 155 includes a non-power-of-two number of memory banks. In an example, if a memory component 155 includes a non-power-of-two number of memory banks, it is determined that the memory component includes one or more defective memory banks and/or has undergone a memory bank remapping process. If the memory component includes a non-power-of-two number of memory banks, a mod division based addressing scheme is implemented and a memory component address is generated for the memory component.

In an example, the addressing system 180 determines whether the memory component 155 includes a non-power-of-two number of memory banks by checking a value of a mode register associated with the memory component 155. In an example, the mode register indicates a number of available memory banks in the memory component 155. If the value in the mode register includes a value that is less than an expected amount of memory banks (or the value in the mode register is not a power of two), the controller 150 determines that the memory component 155 includes one or more defective memory banks and/or has undergone a memory bank remapping process.

For example, if a memory component 155 typically includes thirty-two memory banks but the mode register indicates that the memory component 155 includes thirty memory banks, the controller 150 uses a mod division circuit to generate a memory component addresses for the memory component 155 that includes an intra-bank address and a bank identifier.

As previously discussed, the controller 150 broadcasts the same addresses to a number of different memory components 155 simultaneously. As such, the addressing system 180 helps ensure that each memory bank of each memory component 155 in the memory device 110 is accessible via an address. This process will be described in greater detail below with respect to FIG. 5.

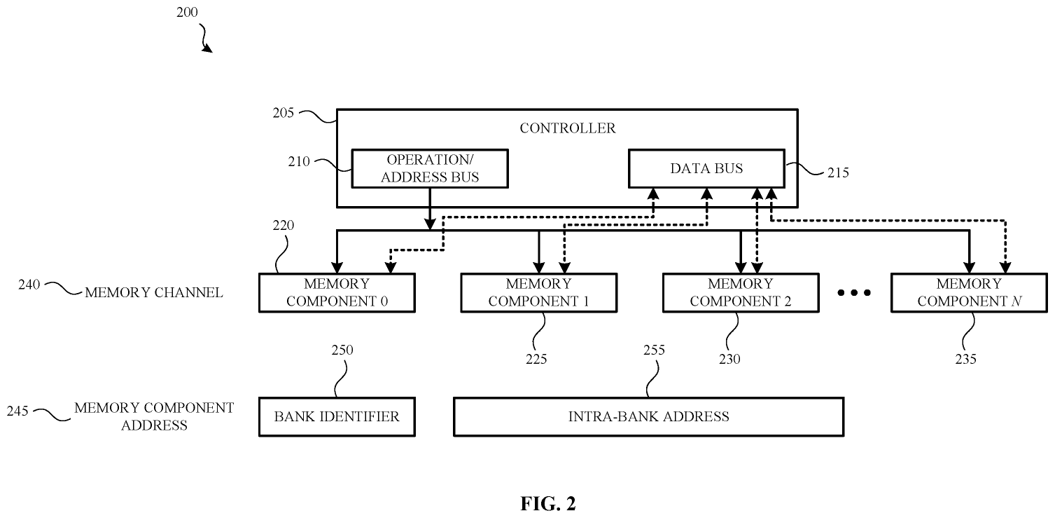

FIG. 2 illustrates a memory device 200 having a controller 205 and a number of memory components according to an example. For example, the memory device 200 includes N memory components-Memory Component 0 220, Memory Component 1 225, Memory Component 2 230 and Memory Component N 235. In an example, the memory components are similar to the memory component 155 shown and described with respect to FIG. 1. As such, each memory component includes two or more memory banks and the number of memory banks are a power of two. In an example, the controller 205 is similar to the controller 150 shown and described with respect to FIG. 1. As such, the controller 205 includes, or is otherwise associated with, an addressing system.

The controller 205 also includes an operation/address bus 210 and a data bus 215. In an example, the operation/address bus 210 is used to simultaneously broadcast operations to each memory component in a single memory channel 240. For example, the controller 205 broadcasts operations, including an associated in-memory component address 245, to Memory Component 0 220, Memory Component 1 225, Memory Component 2 230 and Memory Component N 235. In response, Memory Component 0 220, Memory Component 1 225, Memory Component 2 230 and Memory Component N 235 provides the requested data associated with the address back to the controller 205 using the data bus 215. When the data is received, the controller 205 consolidates the data and returns the data to a requesting device.

In an example, the memory component address 245 includes a bank identifier 250 and an intra-bank address 255. The bank identifier 250 is unique to the memory channel 240 and has to be the same for any of the operations that are broadcast to Memory Component 0 220, Memory Component 1 225, Memory Component 2 230 and Memory Component N 235.

In an example, the bank identifier 250 is the lowest M (e.g., four) address bits of each memory component and the intra-bank address 255 is the remaining K address bits. Thus, if a memory component includes sixteen memory banks, the lowest four address bits would be the bank identifier 250 and the remaining twelve address bits would be the intra-bank address 255.

Although the lowest four bits are used to determine the bank identifier 250, the address bits that are used to generate the bank identifier 250 may be selected from any portion of the address bits. For example, the first four address bits may be used to determine the bank identifier 250. In another example, the middle four address bits may be used to determine the bank identifier 250. Additionally, although four bits are used to generate the bank identifier 250, any number of bits may be used to determine the bank identifier 250.

In an example, the controller 205 and/or an addressing system associated with the controller, determines or otherwise detects whether each memory component includes one or more defective memory banks. For example, the addressing system determines a number of available memory banks in each memory component by checking a value of a mode register associated with each memory component. If the value of the mode register is less than an expected value, the addressing system determines that the memory component includes one or more defective memory banks. In another example, the addressing system determines the memory component includes one or more defective memory banks when the value of the mode register is not a power of two. When it is determined that the memory component includes one or more defective memory banks and/or has undergone a memory bank remapping process, the controller and/or the remapping system generates a bank identifier 250 and/or a intra-bank address 255 for the memory banks and/or the memory component(s).

FIG. 3A illustrates a mapping between a bank identifier 330 of a component address associated with a memory component and physical memory banks 310 of the memory component according to an example. In an example, the memory component is similar to one or more of the memory components shown and described with respect to FIG. 2. Additionally, the mapping 300 occurs as part of a testing phase and/or a sorting phase of a memory component and/or a memory device manufacturing process.

In an example, the mapping 300 is a logical to physical mapping from a bank identifier of a memory component address (e.g., the bank identifier 250 of the memory component address 245 (FIG. 2)) to physical memory banks 310 of the memory component. The mapping 300 is stored by a memory component and/or a memory device of which the memory component is a part.

In this example, the memory component includes thirty-two physical memory banks 310 (e.g., Memory Bank 0-Memory Bank 31). Although thirty-two physical memory banks 310 are shown and described, the memory component may include any number of physical memory banks 310.

In an example, each physical memory bank 310 is associated with an entry in the bank remapping register array 320. For example, Memory Bank 31 315 is associated with the thirty-first entry 325 (indicated by the “31” in the Index/Bank Identifier 330 column) of the bank remapping register array 320. Additionally, each entry in the bank remapping register array 320 is associated with a value that corresponds to the particular physical memory bank. For example, the thirty-first entry 325 in the bank remapping register array 320 has a value of 31 (e.g., Value: 31) which corresponds to Memory Bank 31 315.

In an example, an index of each entry in the bank remapping register array 320 is, or is associated with, a bank identifier (e.g., the bank identifier 250 (FIG. 2)) of a memory component address 245. For example, Memory Bank 31 315 of the physical memory banks 310 is not only associated with the thirty-first entry 325 of the bank remapping register array 320, but is also associated with a bank identifier in the Index/Bank Identifier 330 column. For example, Memory Bank 31 315 is associated with bank identifier 31 355.

The same is true for other entries in the bank remapping register array 320. For example, Memory Bank 30 335 is associated with the thirtieth entry 345 (having a Value: 30) of the bank remapping register array 320. Memory Bank 30 is also associated with a bank identifier 30 380 (indicated by the “30” in the index/bank identifier 330 column). In an example, the addressing system and/or the controller maintains the mapping 300, or stores information about and/or has access to the mapping 300 between the entries in the bank remapping register array 320 and the physical memory banks 310.

In an example, a memory component receives or otherwise uses a memory component address (e.g., memory component address 245 (FIG. 2)) to determine or identify a bank identifier. When the bank identifier is identified or determined, an entry in the bank remapping register array 320 that corresponds to, or is associated with, the bank identifier is identified. The value in the entry of the bank remapping register array 320 indicates the physical memory block 310 associated with the bank identifier.

For example, if bank identifier 31 355 is received or identified by the memory component as part of a broadcast operation, the value (e.g., 31) of the thirty-first entry 325 in the bank remapping register array 320 is determined. Memory Bank 31 315 is then identified as the desired physical memory bank 310.

However, as previously discussed, during a testing phase, the physical memory banks 310 of one or more memory components are tested to determine if one or more of the physical memory banks 310 are defective. If one or more physical memory banks 310 are defective, a bank remapping process is initiated to update the mapping 300. In this example, the results of the testing phase indicate that the memory component includes two defective physical memory banks 310. As shown by the shaded boxes, Memory Bank 3 340 and Memory Bank 28 350 are defective.

When the defective physical memory banks are identified, entries in the bank remapping register array 320 that correspond to the defective memory banks 310 are identified. As shown in FIG. 3A, the entries in the bank remapping register array 320 that correspond to defective Memory Bank 3 340 and defective Memory Bank 28 350 are the twenty-eighth entry 370 (having a Value: 28) and the third entry 360 (having a Value: 3). As also shown in FIG. 3A, the twenty-eighth entry 370 corresponds to bank identifier 28 375 and the third entry 360 corresponds to bank identifier 3 365.

Once the defective physical memory banks 310 are detected, the values of the entries in the bank remapping register array 320 that are associated with the defective physical memory banks 310 are changed or updated as part of a memory bank remapping process. In an example, the values of the entries are changed in the bank remapping register array 320 such that values/entries associated with the available/good physical memory banks 310 are in a first portion of the bank remapping register array 320 and the values/entries associated with the defective physical memory banks 320 are in a second portion of the bank remapping register array 320.

For example and referring to FIG. 3B, FIG. 3B illustrates how entries in the bank remapping register array 320 of FIG. 3A are consolidated during a memory bank remapping process. Once the defective physical memory banks 310 (e.g., physical memory bank 3 340 and physical memory bank 28 350) in the memory component are identified, the memory bank remapping process updates the values of entries within the bank remapping register array 320.

In an example, when a value of an entry in the bank remapping register array 320 is updated, that entry is mapped to a different physical memory bank 310. For example, during the memory bank remapping process, an available physical memory bank is identified. Additionally, an entry in the bank remapping register array 320 associated with the available physical memory bank is also identified. The value of the entry in the bank remapping register array 320 associated with the available physical memory bank is then changed with, or updated using, the value of the entry in the bank remapping register array 320 associated with the defective memory bank. Additionally, The value of the entry in the bank remapping register array 320 associated with the defective physical memory bank is then changed with, or updated using, the value of the entry in the bank remapping register array 320 associated with the available memory bank.

In an example, the number of defective physical memory banks is identified before the memory bank remapping process is initiated. As such, entries at one portion (e.g., the end) of the bank remapping register array 320 are selected for the memory bank remapping process. For example, entries 31, 30, 29 in the bank remapping register array 320 (and corresponding bank identifiers) are selected to ultimately map to the defective memory banks.

Returning to the example shown in FIG. 3B, because Memory Bank 3 340 is defective, the value of the third entry 360 in the bank remapping register array 320 is changed from 3 to 30. This change remaps the memory component address (e.g., memory component address 245 (FIG. 2)) associated with bank identifier 3 365 to Memory Bank 30 395 instead of Memory Bank 3 340. For example and as shown in FIG. 3B, the third entry 360 in the bank remapping register array 320 points to Memory Bank 30 335.

Additionally, because Memory Bank 28 350 is defective, the value of the twenty-eighth entry 370 of the bank remapping register array 320 is changed from 28 to 31. This change remaps the memory component address (e.g., memory component address 245 (FIG. 2)) associated with bank identifier 28 375 to Memory Bank 31 315 instead of Memory Bank 28 350. For example and as shown in FIG. 3B, the twenty-eighth entry 370 in the bank remapping register array 320 points to Memory Bank 31 315.

In an example, memory component addresses associated with the defective physical memory banks 310 are also updated and/or remapped. For example, the memory component address associated with bank identifier 30 380 is remapped to Memory Bank 3 340. In an example, the bank identifier 30 380 is remapped to the Memory Bank 3 340 by updating or changing the value of the thirtieth entry 345 in the bank remapping register array 320. For example, the thirtieth entry 345 in the bank remapping register array 320 is changed from a 30 to a 3. As such, the thirtieth entry 345 in the bank remapping register array 320 points to Memory Bank 3 340.

Likewise, the memory component addresses associated bank identifier 31 355 is also remapped. For example, the bank identifier 31 355 is remapped to Memory Bank 28 350 by updating or changing the value of the thirty-first 325 in the bank remapping register array 320 from a 31 to a 28. As such, the thirty-first entry 325 in the bank remapping register array 320 points to Memory Bank 28 350.

In an example, as part of the memory bank remapping process, a determination is made regarding the available/good physical memory banks of the memory component. The number of available/good memory banks is stored in a mode register 385. In this example, the number of available/good memory banks indicated by the mode register 385 is thirty.

In another example, memory components that have the same defective memory bank are grouped as part of a sorting process. In an example, this grouping is used in lieu of remapping. For example, if Memory Bank 3 340 is defective on first memory component and a second memory component, the sorting process groups the first memory component and the second memory component. Likewise, if Memory Bank 3 340 and Memory Bank 28 350 were defective on a third memory component and a fourth memory component, the sorting process would group these two memory components. The grouped memory components would then be placed or otherwise provided in the same memory device.

In this example, a bank remapping register array (e.g., the bank remapping register array 175 (FIG. 1)) is included as part of a controller (e.g., the controller 150) instead of the memory component (e.g., memory component 155). As a result, the memory component address (e.g., memory component address 245 (FIG. 2)) of each memory component consists of an index of memory banks and an intra-bank address 255 (e.g., intra-bank address 255) instead of a bank identifier 250.

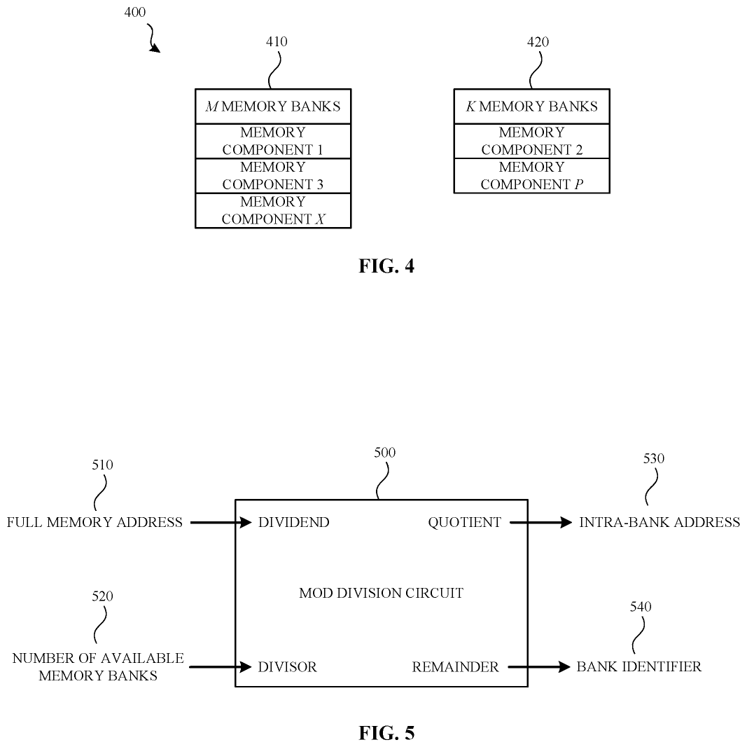

FIG. 4 illustrates how memory components having the same number of available memory banks are grouped to form ranks 400 according to an example. In an example, the groups are formed as part of a sorting phase and/or a remapping phase of a manufacturing process. In this example, two groups or ranks 400 of memory components are formed based on the number of available memory banks in each memory component. For example, a first rank 410 includes memory components having M available/good memory banks and a second rank 420 includes memory components having K available/good memory banks. As shown in FIG. 4, Memory Component 1, Memory Component 3 and Memory Component X have M available/good memory banks and Memory Component 2 and Memory Component P have K available memory banks.

When the memory components have defective memory banks, these memory components have a non-power-of-two number of memory banks. As such, new memory component addresses, including bank identifiers and intra-bank addresses, for the memory components need to be generated.

FIG. 5 illustrates how a memory component address having a bank identifier 540 and an intra-bank address 530 is generated for a memory component having a non-power-of-two number of memory banks according to an example. In an example, a mod division circuit 500 of a controller is used to determine and/or generate the memory component address having the bank identifier 540 and the intra-bank address 530. Although a mod division circuit 500 is specifically mentioned, other circuitry and/or systems may be used to generate or determine a bank identifier 540 and/or an intra-bank address 530 for memory components having a non-power-of-two number of memory banks.

In an example, the mod division circuit 500 receives the full memory address 510 (or an initial memory address) of a memory component having the non-power-of-two number of memory banks. The full memory address 510 is divided by the number of available memory banks 520. In an example, the number of available memory banks is stored by a mode register associated with the memory component. The remainder of this calculation will be equivalent to the bank identifier 540 for the memory component. Additionally, the quotient of this calculation will be the intra-bank address 530 of the memory component.

In an example in which memory components having the same defective memory bank locations are grouped, the controller and/or an addressing system performs a bank identifier 540 to physical memory bank remapping inside the controller. In this implementation, the controller includes a bank remapping register array (e.g., the bank remapping register array 185). During the remapping process, the full memory address 510 of each memory component consists of an index of memory banks and an intra-bank address 530 instead of a bank identifier 540.

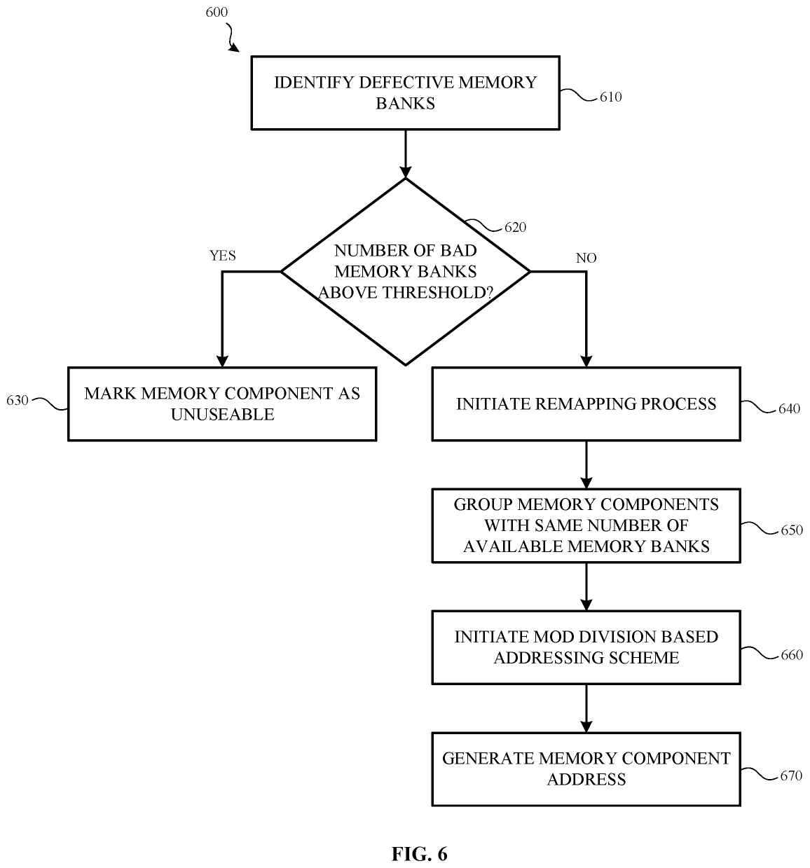

FIG. 6 illustrates a method 600 for remapping memory banks of a memory component according to an example. In an example, the method 600 (or portions of the method 600) is performed as part of a memory component testing process.

In an example, the method 600 begins when one or more defective memory banks of a memory component are identified (610). In an example, a testing phase of a memory component manufacturing process identifies or determines whether the memory component has one or more defective memory banks.

If one or more defective memory banks are detected or identified, a determination is made (620) as to whether the number of defective memory banks is over a threshold. In an example, the threshold may be any number and is based, at least in part, on a number of factors. These factors include, but are not limited to, whether it would be profitable and/or feasible to manufacture memory devices having over the threshold number of defective memory banks.

If it is determined (620) that the number of defective memory banks is over the threshold, the memory component is marked (630) as unusable and may be destroyed or otherwise not included as part of a memory device. The method 600 may then repeat for another memory component.

However, if it is determined (620) that the number of bad/defective memory banks is below the threshold (or if it is determined that a number of available memory banks is above a threshold but the memory component includes a non-power-of-two number of memory banks), a remapping process is initiated (640). In an example, as part of the remapping process, a bank remapping register array associated with the memory component is accessed. Each entry in the bank remapping register array corresponds to a physical memory bank of the memory component.

For example, each entry in the bank remapping register array includes a value that is associated with a particular physical memory bank of the memory component. The value indicates a logical to physical mapping between a bank identifier (e.g., bank identifier 250 (FIG. 2)) and the physical memory bank of the memory component. For example, a first entry in the bank remapping register array points to a first physical location of a first memory bank of the memory component. Likewise, a second entry in the bank remapping register array points to a second physical location of a second memory bank of the memory component.

During the remapping process, bank identifiers are consolidated such that bank identifiers that are associated with available/good physical memory banks are ordered consecutively (e.g., from bank identifier 0 to bank identifier (N−X−1) (where X is the number of defective memory banks). In an example, the bank identifiers are consolidated by changing values of corresponding entries in the bank remapping register array such as previously described.

When the remapping process is complete, a sorting process is initiated. In the sorting process, memory components having the same number of available memory banks are grouped (650). For example, if the memory components have a total of thirty-two memory banks, memory components having thirty-two memory banks are identified or are otherwise placed in a first group, memory components having thirty-one memory banks are identified and/or placed in a second group, memory components having thirty memory banks are identified and/or placed in a third group and so on.

When the memory components are grouped memory components having the same number of available memory banks are included as part of a memory device. A controller of the memory device checks a mode register (e.g., mode register 385 (FIG. 3B)) of each memory component to determine whether a mod division based addressing mechanism is needed. If so, a mod-based addressing scheme/process (660) is initiated and a memory component address for the memory component is generated (670).

In an example, the bank identifier and the intra-bank address is based, at least in part, on the full memory address associated with the memory component and the number of available memory banks of the memory component. For example, a mod division circuit of the controller divides the full memory address of the memory component by the number of available memory banks in the memory component. The quotient is the intra-bank address and the remainder is the bank identifier.

In accordance with the present disclosure examples describe a method, comprising: identifying a defective memory bank of a memory component, the memory component having a plurality of memory banks, wherein each memory bank of the plurality of memory banks is associated with an entry in a bank remapping register array that indicates a logical to physical mapping between a bank identifier of a memory component address associated with the memory component and a corresponding memory bank of the plurality of memory banks; and performing a remapping process, the remapping process including updating a value of an entry in the bank remapping register array that is associated with the defective memory bank, wherein updating the value of the entry in the bank remapping register array consolidates entries in the bank remapping register array that are associated with available memory banks of the plurality of memory banks. In an example, in the remapping process, entries in the bank remapping register array are updated such that the available physical memory banks are logically mapped in a consecutive order. In an example, the remapping process further comprises replacing the value of the entry in the bank remapping register array that is associated with the available memory bank with the value associated with the entry in the bank remapping register array that is associated with the defective memory bank. In an example, the method includes identifying one or more additional memory components having a number of available memory banks that match a number of available memory banks of the memory component; and grouping the additional one or more memory components with the memory component. In an example, the method includes determining whether to generate a new memory component address for the memory component. In an example, the determination is based, at least in part, on determining whether a value in a mode register associated with the memory component indicates the memory component has a non-power-of-two number of memory banks. In an example, the new memory component address is generated by dividing the memory component address by a number of the available memory banks of the plurality of memory banks. In an example, the memory component address is divided by the number of available memory banks using a mod division circuit. In an example, a bank identifier of the new memory component address is a remainder of the division of the memory component address and the number of available memory banks and an intra-bank address of the new memory component address is a quotient of the division of the memory address and the number of available memory banks.

Examples also describe a memory device, comprising: one or more memory components, each of the one or more memory components including a plurality of memory banks; and a controller communicatively coupled to the one or more memory components and operable to: determine whether at least one memory component of the one or more memory components includes a non-power-of-two number of memory banks; and based, at least in part, on determining the at least one memory component includes the non-power-of-two number of memory banks, generate a memory component address for the at least one memory component. In an example, the controller determines whether the at least one memory component of the one or more memory components includes a non-power-of-two number of memory banks by checking a value stored in a mode register associated with the at least one memory component. In an example, the memory device also includes a mod division circuit, wherein the mod division circuit generates the memory component address for the at least one memory component. In an example, the mod division circuit generates the memory component address for the at least one memory component by dividing an initial memory component address associated with the at least one memory component by a number of available memory banks of the at least one memory component. In an example, a remainder of the division of the initial memory component address and the number of available memory banks is a bank identifier of the memory component address and wherein a quotient of the division of the initial memory component address and the number of available memory banks is an intra-bank address of the memory component address. In an example, the number of available memory banks is based, at least in part, on a value stored in a mode register associated with the memory component.

Examples also describe a memory device, comprising: means for determining whether a memory component includes a non-power-of-two number of memory means; and means for generating a new memory component address for the memory component having the non-power-of-two number of memory means. In an example, the memory device also includes a mode register means that indicates whether the memory component includes the non-power-of-two number of memory means. In an example, the means for generating the new memory component address for the memory component includes a means for dividing an initial memory component address associated with the memory component by a number of available memory means. In an example, a remainder of the division of the initial memory component address and the number of available memory means is a bank identifier of the new memory component address and wherein a quotient of the division of the initial memory component address and the number of available memory means is an intra-bank address of the new memory component address. In an example, the number of available memory means is based, at least in part, on a value of a register means associated with the memory component.

One of ordinary skill in the art will recognize that the technology described herein is not limited to a single specific memory structure, but covers many relevant memory structures within the spirit and scope of the technology as described herein and as understood by one of ordinary skill in the art.

The technology described herein refers to emerging memory technologies, such as ReRAM, Phase Change Memory (PCM) and magneto-resistive ram (MRAM). Additionally, examples described herein may be discussed in the general context of computer-executable instructions residing on some form of computer-readable storage medium, such as program modules, executed by one or more computers or other devices. By way of example, and not limitation, computer-readable storage media may comprise non-transitory computer storage media and communication media. Generally, program modules include routines, programs, objects, components, data structures, etc., that perform particular tasks or implement particular abstract data types. The functionality of the program modules may be combined or distributed as desired in various examples.

Communication media may be embodied by computer readable instructions, data structures, program modules, or other data in a modulated data signal, such as a carrier wave or other transport mechanism, and includes any information delivery media. The term “modulated data signal” may describe a signal that has one or more characteristics set or changed in such a manner as to encode information in the signal. By way of example, and not limitation, communication media may include wired media such as a wired network or direct-wired connection, and wireless media such as acoustic, radio frequency (RF), infrared, and other wireless media.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

Aspects of the present disclosure have been described above with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A method, comprising:
identifying a defective memory bank of a memory component, the memory component having a plurality of memory banks, wherein each memory bank of the plurality of memory banks is associated with an entry in a bank remapping register array that indicates a logical to physical mapping between a bank identifier of a memory component address associated with the memory component and a corresponding memory bank of the plurality of memory banks; and
performing a remapping process, the remapping process including updating a value of an entry in the bank remapping register array that is associated with the defective memory bank, wherein updating the value of the entry in the bank remapping register array consolidates entries in the bank remapping register array that are associated with available memory banks of the plurality of memory banks.

2. The method of claim 1, wherein in the remapping process, entries in the bank remapping register array are updated such that the available physical memory banks are logically mapped in a consecutive order.

3. The method of claim 1, wherein the remapping process further comprises replacing the value of the entry in the bank remapping register array that is associated with the available memory bank with the value associated with the entry in the bank remapping register array that is associated with the defective memory bank.

4. The method of claim 1, further comprising:
identifying one or more additional memory components having a number of available memory banks that match a number of available memory banks of the memory component; and
grouping the additional one or more memory components with the memory component.

5. The method of claim 1, further comprising determining whether to generate a new memory component address for the memory component.

6. The method of claim 5, wherein the determination is based, at least in part, on determining whether a value in a mode register associated with the memory component indicates the memory component has a non-power-of-two number of memory banks.

7. The method of claim 6, wherein the new memory component address is generated by dividing the memory component address by a number of the available memory banks of the plurality of memory banks.

8. The method of claim 7, wherein the memory component address is divided by the number of available memory banks using a mod division circuit.

9. The method of claim 8, wherein a bank identifier of the new memory component address is a remainder of the division of the memory component address and the number of available memory banks and an intra-bank address of the new memory component address is a quotient of the division of the memory address and the number of available memory banks.

10. A memory device, comprising:
one or more memory components, each of the one or more memory components including a plurality of memory banks; and
a controller communicatively coupled to the one or more memory components and operable to:
determine whether at least one memory component of the one or more memory components includes a non-power-of-two number of memory banks; and
based, at least in part, on determining the at least one memory component includes the non-power-of-two number of memory banks, generate a memory component address for the at least one memory component.

11. The memory device of claim 10, wherein the controller determines whether the at least one memory component of the one or more memory components includes a non-power-of-two number of memory banks by checking a value stored in a mode register associated with the at least one memory component.

12. The memory device of claim 10, further comprising a mod division circuit, wherein the mod division circuit generates the memory component address for the at least one memory component.

13. The memory device of claim 12, wherein the mod division circuit generates the memory component address for the at least one memory component by dividing an initial memory component address associated with the at least one memory component by a number of available memory banks of the at least one memory component.

14. The memory device of claim 13, wherein a remainder of the division of the initial memory component address and the number of available memory banks is a bank identifier of the memory component address and wherein a quotient of the division of the initial memory component address and the number of available memory banks is an intra-bank address of the memory component address.

15. The memory device of claim 13, wherein the number of available memory banks is based, at least in part, on a value stored in a mode register associated with the memory component.

16. A memory device, comprising:
means for determining whether a memory component includes a non-power-of-two number of memory means; and
means for generating a new memory component address for the memory component having the non-power-of-two number of memory means.

17. The memory device of claim 16, further comprising a mode register means that indicates whether the memory component includes the non-power-of-two number of memory means.

18. The memory device of claim 16, wherein the means for generating the new memory component address for the memory component includes a means for dividing an initial memory component address associated with the memory component by a number of available memory means.

19. The memory device of claim 18, wherein a remainder of the division of the initial memory component address and the number of available memory means is a bank identifier of the new memory component address and wherein a quotient of the division of the initial memory component address and the number of available memory means is an intra-bank address of the new memory component address.

20. The memory device of claim 18, wherein the number of available memory means is based, at least in part, on a value of a register means associated with the memory component.
